(19) United States
(12) Patent Application Publication
(10) Pub. No.: US 2009/0095968 A1
(43) Pub. Date: Apr. 16, 2009

(54) Image Sensor and Method for Manufacturing the Same

(76) Inventors: In Cheol Baek, Suwon-si (KR); Han Choon Lee, Songpa-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/209,331

(22) Filed: Sep. 12, 2008

(30) Foreign Application Priority Data
Oct. 11, 2007 (KR) 10-2007-0102353

(51) Int. Cl. H01L 33/00; H01L 21/00

(52) U.S. Cl. 257/98; 438/70; 438/98; 257/E33.072

(57) ABSTRACT

Provided are an image sensor and a method for manufacturing the same. A trench can be formed through metal interconnection layers of the image sensor in a region corresponding to a light receiving device for each unit pixel. A passivation layer pattern can be provided at sidewalls of the trench to inhibit light incident into the metal interconnection layers and reduce cross-talk and noise. A filler material can be provided to fill the trench. A color filter layer and microlens can be formed on the filler material. The filler material can be, for example, a polymer, an oxide layer, or a photoresist.

### CROSS-REFERENCE TO RELATED APPLICATION

The present application claims the benefit under 35 U.S.C. §119 of Korean Patent Application No. 10-2007-0102353, filed Oct. 11, 2007, which is hereby incorporated by reference in its entirety.

### BACKGROUND

An image sensor is a semiconductor device that converts an optical image to an electric signal. The image sensor is generally classified as a charge coupled device (CCD) or a complementary metal oxide semiconductor (CMOS) image sensor (CIS).

The CIS includes a photodiode and a MOS transistor in a unit pixel. The CIS sequentially detects electric signals of unit pixels in a switching manner to realize an image.

### BRIEF SUMMARY

Embodiments of the present invention provide an image sensor and method for manufacturing the same capable of reducing crosstalk between unit pixels.

In one embodiment, an image sensor can include: a semiconductor substrate comprising a light receiving device; a metal interconnection layer on the semiconductor substrate, the metal interconnection layer comprising a trench in which passivation layer patterns are disposed on sidewalls thereof; and a filler material on the metal interconnection layer and the passivation layer patterns, the filler material filling the trench.

In another embodiment, a method for manufacturing an image sensor can include: forming a metal interconnection layer on a semiconductor substrate comprising a light receiving device; forming a trench through the metal interconnection layer; forming a passivation layer on the metal interconnection layer including the trench; performing a blanket etch process on the the passivation layer to form passivation layer patterns on sidewalls of the trench; and forming a filler material on the metal interconnection layer to fill the trench.

The details of one or more embodiments are set forth in the accompanying drawings and the description below. Other features will be apparent from the description and drawings, and from the claims.

### BRIEF DESCRIPTION OF THE DRAWINGS

FIGS. 1 to 5 are cross-sectional views of a process for manufacturing an image sensor according to an embodiment of the present invention.

### DETAILED DESCRIPTION

Hereinafter, embodiments of an image sensor and method for manufacturing the same will be described in detail with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Although a CMOS image sensor (CIS) will be described in the following embodiments, the present invention is not limited thereto. Instead, elements may also be applied to various types of image sensors, such as a CCD image sensor.

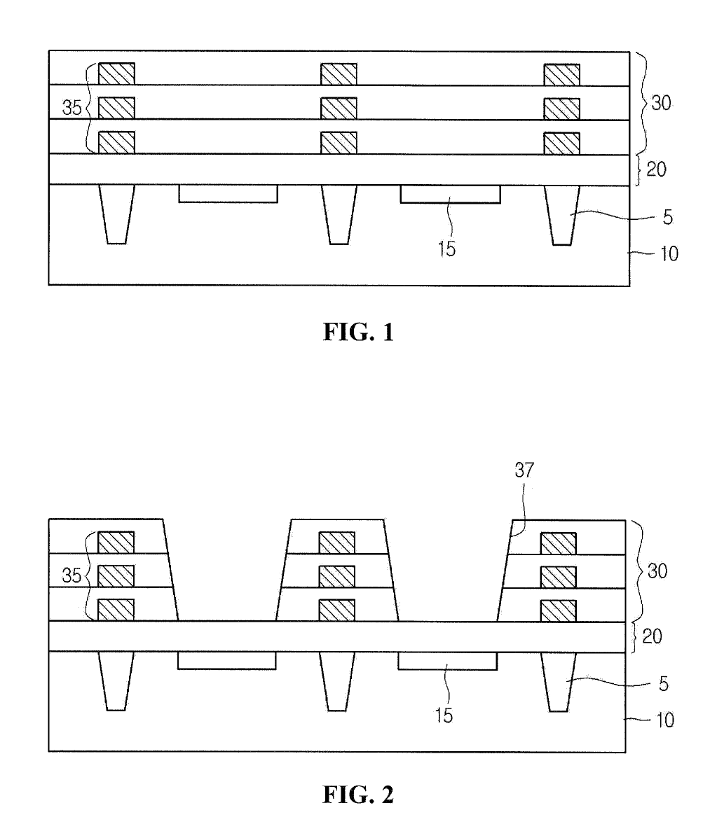

FIGS. 1 to 5 are cross-sectional views of a process for manufacturing an image sensor according to an embodiment.

Referring to FIG. 1, a circuit layer 20 and a metal interconnection layer 30 can be formed on a semiconductor substrate 10.

The semiconductor substrate 10 can include a device isolation layer 5 and a light receiving device 15. A circuit including a transistor can be formed in the circuit layer 20. An interconnection 35 connected to the circuit can be formed in the metal interconnection layer 30. The metal interconnection layer 30 can be formed of a plurality of layers. In addition, the interconnection 35 can be formed in plurality and can be formed using multiple metal layers.

In an embodiment, the light receiving device 15 can include a photodiode.

Referring to FIG. 2, a trench 37 is formed in the metal interconnection layer 30.

In one embodiment, the trench 37 can be formed by forming a photoresist pattern on the metal interconnection layer 30, and performing an etch process through the layers of the metal interconnection layer 30 using the photoresist pattern as an etch mask.

The trench 37 is formed in a region of the metal interconnection layer 30 corresponding to the light receiving device 15.

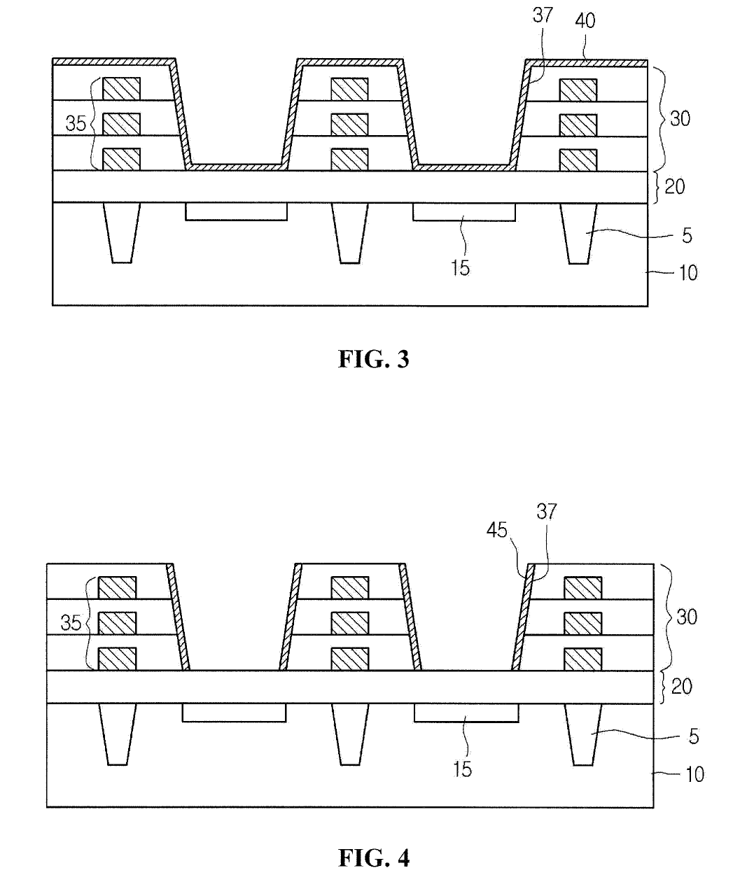

Referring to FIG. 3, a passivation layer 40 can be formed on the metal interconnection layer 30 including the trench 37.

The passivation layer 40 can be formed of silicon nitride SiN. In one embodiment, the passivation layer 40 can have a thickness ranging from about 300 A to about 700 A.

The passivation layer 40 can be used to inhibit incident light from being incident to the metal interconnection layer 30.

Referring to FIG. 4, an anisotropic etching process, such as a plasma blanket etch process can be performed on the semiconductor substrate 10 including the trench 37 and the metal interconnection layer 30 such that the passivation layer 40 remains only on sidewalls of the trench 37. This remaining passivation layer 40 can be referred to as passivation layer patterns 45.

The plasma blanket etch process, which is an etch process having excellent directionality by applying large bias voltage, can be performed to remove all the passivation layer 40 formed on a bottom surface of the trench 37 and a top surface of the metal interconnection layer 30. As a result, the passivation layer patterns 45 are formed on the sidewalls of the trench 37.

The passivation layer 40 formed on the bottom surface of the trench 37 is removed to improve light transmittance, thereby increasing an amount of light incident to the light receiving device 15.

When light is incident toward the metal interconnection 35, the light can be inhibited from being incident inside the metal interconnection layer 30 because of the passivation layer 40 formed on the sidewalls of the trench 37. Therefore, cross talk and noise can be reduced.

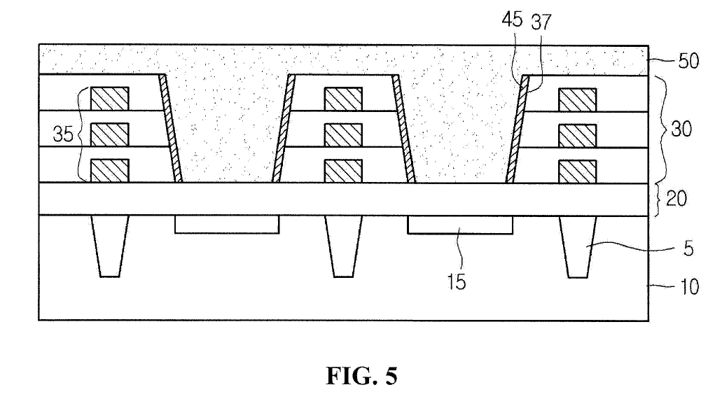

Referring to FIG. 5, a filler material can be formed on the metal interconnection layer 30 to fill the trench 37. A portion of the filler material can remain on the top surface of the metal interconnection layer 30. In certain embodiments, the portions of the filler material not in the trench 37 can be removed. The filler material 50 can be a photosensitive material. The photosensitive material can be coated on the substrate 10 to fill the trench 37.

An oxide layer, a polymer, or a photoresist can be used as the filler material 50.

In further embodiments, although not shown, a color filter array and a micro lens can be formed on the filler material 50.

Accordingly, an image sensor according to an embodiment includes a semiconductor substrate 10, a metal interconnection layer 30, and a passivation layer pattern provided at sidewalls of a trench in the metal interconnection layer 30. A light receiving device 15 is disposed in the semiconductor substrate 10. The trench 37 is disposed in the metal interconnection layer 30 at a region corresponding to the light receiving device 15. Passivation layer patterns 45 are disposed on sidewalls of the trench 37. A filler material 50 is disposed on the metal interconnection layer 30 including in the trench 37. The filler material can contribute to a wave guide function for directing light towards the light receiving device 15. The filler material 50 can be, for example, an oxide layer, a polymer, or a photoresist.

A device isolation layer 5 and the light receiving device 15 can be disposed in the semiconductor substrate 10. A circuit including a transistor can be disposed in a circuit layer 20. An interconnection 35 connected to the circuit can be disposed in the metal interconnection layer 30.

In certain embodiments, the light receiving device 15 can be a photodiode.

The trench 37, having the passivation layer patterns 45 disposed on the sidewalls thereof, is formed in a region of the metal interconnection layer 30 corresponding to the light receiving device 15.

Each of the passivation layer patterns 45 can be formed of SiN. The passivation layer patterns 45 can have a thickness ranging from about 300 A to about 700 A.

As described above, in the image sensor and a method for manufacturing the same according to embodiments, a filler material is disposed in a trench formed through a metal interconnection layer 30 in which passivation layer patterns are disposed on the sidewalls thereof, thereby improving the sensitivity of the image sensor.

In addition, when light is incident toward the metal interconnection, the light can inhibited from being incident inside the metal interconnection layer because of the passivation layer formed on the sidewalls of the trench, thereby reducing cross talk and noise of the image sensor.

Any reference in this specification to “one embodiment,” “an embodiment,” “exemplary embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing an image sensor comprising:
forming a light receiving device in a pixel region of a substrate;
forming a metal interconnection layer including metal interconnections on the substrate;
forming a trench through the metal interconnection layer between the metal interconnections in a region corresponding to the light receiving device;
forming passivation layer patterns at sidewalls of the trench; and
forming a filler material on the metal interconnection layer to fill the trench.

2. The method according to claim 1, wherein forming the trench comprises etching through the entire metal interconnection layer, exposing a lower layer.

3. The method according to claim 1, wherein forming passivation layer patterns at sidewalls of the trench comprises:
forming a passivation layer on the metal interconnection layer, including in the trench; and
performing an anisotropic etching process.

4. The method according to claim 3, wherein performing the anisotropic etching process comprises performing a plasma blanket etch.

5. The method according to claim 3, wherein performing the anisotropic etching process comprises removing portions of the passivation layer from a bottom of the trench and a top surface of the metal interconnection layer.

6. The method according to claim 1, wherein forming passivation layer patterns at sidewalls of the trench comprises:
depositing a silicon nitride layer on the metal interconnection layer, including in the trench.

7. The method according to claim 6, wherein the silicon nitride layer is deposited to a thickness of between about 300 Å to about 700 Å.

8. The method according to claim 1, wherein forming a filler material comprises:
coating a photosensitive material layer on the substrate, filling the trench.

9. The method according to claim 1, wherein the filler material comprises an oxide layer.

10. The method according to claim 1, wherein the filler material comprises a polymer material.

11. The method according to claim 1, wherein the filler material comprises a photoresist.

12. The method according to claim 1, further comprising:
forming a color filter array on the filler material; and
forming microlenses on the color filter array.

13. An image sensor, comprising:
a light receiving device in a pixel region of a substrate;
a metal interconnection layer including metal interconnections on the substrate, wherein the metal interconnection layer comprises a trench passing between the metal interconnections in a region corresponding to the light receiving device;
a passivation layer pattern provided at sidewalls of the trench; and
a filler material filling the trench and in contact with a bottom of the trench.

14. The image sensor according to claim 13, wherein the trench passes through the entire metal interconnection layer.

15. The image sensor according to claim 13, wherein the passivation layer pattern comprises silicon nitride.

16. The image sensor according to claim 13, wherein the passivation layer has a thickness in the range of about 300 Å to about 700 Å.

17. The image sensor according to claim 13, wherein the filler material comprises an oxide layer.

18. The image sensor according to claim 13, wherein the filler material comprises a polymer material.

19. The image sensor according to claim 13, wherein the filler material comprises a photoresist.

20. The image sensor according to claim 13, further comprising:
a color filter on the filler material; and
a microlens on the color filter.
